(19) United States
(12) Patent Application Publication
(10) Pub. No.: US 2007/0262341 A1
(43) Pub. Date: Nov. 15, 2007

(54) VERTICAL LED WITH EUTECTIC LAYER

(76) Inventors: WEN-HUANG LIU, Guan-Xi Town (TW); Jui-Kang Yen, Taipei City (TW)

Correspondence Address: PATTERSON & SHERIDAN, L.L.P., 3040 POST OAK BOULEVARD, SUITE 1500, HOUSTON, TX, 77056, US

(21) Appl. No.: 11/382,296

(22) Filed: May 9, 2006

(51) Int. Cl. H01L 33/00

(52) U.S. Cl. 257/103

(57) ABSTRACT

A vertical light-emitting diode (VLED) structure with a eutectic layer is described. The eutectic layer improves the heat conductivity of the device, thereby leading to increased brightness and higher luminous efficiency. The eutectic bonds of this layer also improve the reliability of the VLED structure since they have a lower coefficient of thermal expansion (CTE). A metal protective layer may be included to prevent diffusion of the eutectic layer thereby increasing the reliability and lifetime of the VLED structure. A reflective layer and/or a patterned surface may be added to this structure to further enhance the emitted light and increase the luminous efficiency.

### BACKGROUND OF THE INVENTION

### Field of the Invention

The invention relates to the field of light-emitting diode (LED) technology and, more particularly, to a vertical light-emitting diode (VLED) structure.

### DESCRIPTION OF THE RELATED ART

Light-emitting diodes (LEDs) have been around for several decades, and research and development efforts are constantly being directed towards improving their luminous efficiency, thereby increasing the number of possible applications. The primary limiting factor on improving luminous efficiency has been heat dissipation, and therefore, heat transfer management is a major concern for designers of LEDs.

When LEDs are driven with high currents, high device temperatures may occur because of insufficient heat transfer from the active layer of the semiconductor die to the ambient environment. Not only can high temperatures lead to device degradation and accelerated aging, but the optical properties of the LED vary with temperature, as well. As an example, the light output of an LED typically decreases with increased device temperature. Also, the emitted wavelength can change with temperature due to a change in the semiconductor bandgap energy.

Conventional LED structures have been formed on substrates such as sapphire, silicon carbide, silicon, germanium, ZnO, or gallium arsenide. These materials are thermal insulators or have poor heat conducting properties. The vertical light-emitting diode (VLED) structure has been created to improve heat dissipation by replacing the substrate of conventional LEDs with better heat conducting materials, such as molybdenum, through gluing or bonding the device layers with a silver epoxy or paste followed by laser lifting off or etching away the original substrate. The VLED earned its name because the thin epitaxial layers of the structure are sandwiched between the n and p electrodes. To further improve heat dissipation, recent VLED structures called metal vertical photon LEDs (MvpLEDs) have replaced substrates composed of poor heat-conductive materials, such as SiO2 or sapphire, with metal-based substrates without using a glue layer or a bonding layer. Instead, MvpLEDs use deposition techniques, such as electro or electroless chemical deposition, to form the metal-based substrate directly adjacent to the device layers without an intermediate glue or bonding layer to impede heat conduction.

Still, the main path for heat dissipation in prior art is from the active layer of the LED stack through the metal-based substrate and a relatively thick silver epoxy layer to a metal lead frame or pads of a printed circuit board (PCB) via heat conduction. The problem with this design is that the silver epoxy has a low thermal conductivity and a high thermal coefficient of expansion (CTE). With such a low thermal conductivity, the relatively thick layer of silver epoxy can act somewhat like a thermal resistor. With the relatively high CTE, prior art VLEDs may also have reduced reliability at high temperatures and over time due to stress caused by expansion and contraction of the silver epoxy layer.

Accordingly, what is needed is an improved technique to fabricating VLEDs, preferably that improves luminous efficiency, exhibits greater heat dissipation, and increases reliability.

### SUMMARY OF THE INVENTION

One embodiment of the invention provides a vertical light-emitting diode (VLED) structure. The structure generally includes a eutectic layer, a metal-based substrate disposed adjacent to the eutectic layer, a light-emitting diode stack disposed above the substrate, and an electrode connected to the light-emitting diode stack. Some embodiments may include a reflective layer to help direct light in a single direction thereby increasing luminous efficiency and/or a metal protective layer for better adhesion and hence, enhanced reliability.

Another embodiment of the invention provides a vertical light-emitting diode (VLED) structure. The structure generally includes a lead frame, a metal-based substrate, a eutectic layer disposed between the lead frame and the metal-based substrate, a light-emitting diode stack disposed above the substrate, and an electrode connected to the light-emitting diode stack. Some embodiments may include a reflective layer to help direct light in a single direction thereby increasing luminous efficiency and/or a metal protective layer for better adhesion and hence, enhanced reliability.

Another embodiment of the invention provides a vertical light-emitting diode (VLED) structure. The structure generally includes a eutectic layer, a lead frame disposed above the eutectic layer, a bonding layer disposed between the lead frame and a metal-based substrate, a light-emitting diode stack disposed above the substrate, and an electrode connected to the light-emitting diode stack. The bonding layer may be a second eutectic layer. Some embodiments may include a reflective layer to help direct light in a single direction thereby increasing luminous efficiency and/or a metal protective layer for better adhesion and hence, enhanced reliability.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional schematic representation of a VLED with a eutectic layer according to one embodiment of the invention;

FIG. 2 is a cross-sectional schematic representation of a VLED with a eutectic layer and a metal protective layer according to one embodiment of the invention;

FIG. 3 is a cross-sectional schematic representation of a VLED with a eutectic layer portraying the patterned surface of the LED stack according to one embodiment of the invention;

FIG. 4 is a cross-sectional schematic representation of a VLED with a eutectic layer and a lead frame according to one embodiment of the invention;

FIG. 5 is a cross-sectional schematic representation of a VLED with a eutectic layer, a metal protective layer, and a lead frame according to one embodiment of the invention; and

FIG. 6 is a cross-sectional schematic representation of a VLED with a bonding layer, a lead frame, and a eutectic layer according to one embodiment of the invention.

### DETAILED DESCRIPTION

Embodiments of the present invention provide a vertical light-emitting diode (VLED) structure that may be incorporated into MvpLEDs and may provide an improved heat transfer path and increased reliability over conventional VLEDs.

An Exemplary LED Structure

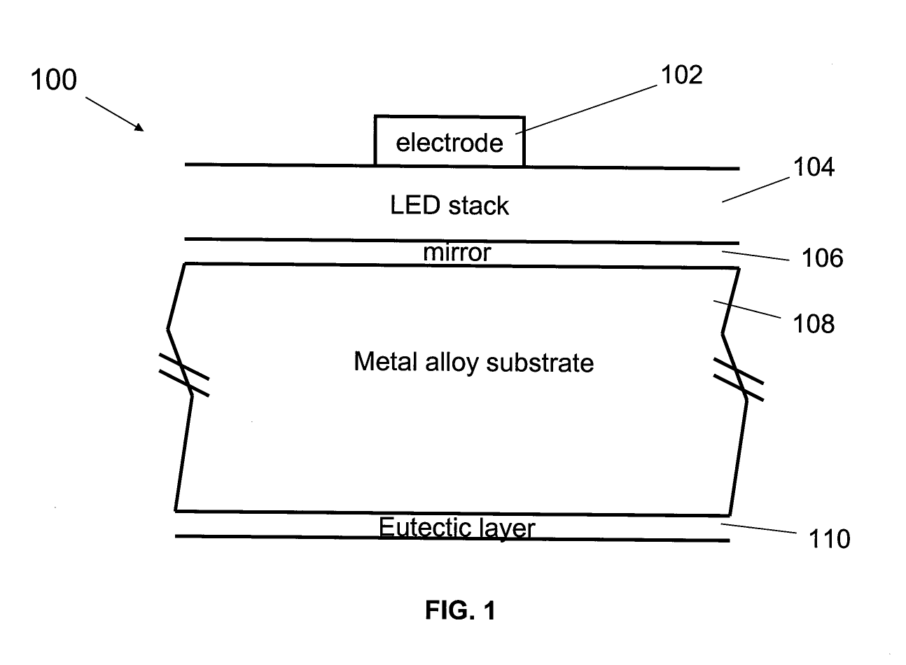

FIG. 1 is a cross-sectional schematic representation of a VLED structure 100 with a eutectic layer 110 according to one embodiment of the invention. An essential component of any VLED structure, an LED stack 104 is depicted and may comprise any suitable materials, such as AlGaInN or AlGaInP, below which a substrate 108 may be situated. Typically dimensioned with a thickness of 10 to 400 μm, the substrate 108 may comprise a single layer or multiple layers, and in any event, may consist of a single element or combinations of suitable metals or metal alloys, such as Cu, Ni, Ag, Au, Al, Cu—Co, Ni—Co, Cu—W, Cu—Mo, Ni/Cu, or Ni/Cu—Mo. The materials of the substrate 108 may be selected to be capable of forming eutectic bonds with the eutectic layer 110. Therefore, metal alloys may typically be used as opposed to sapphire or other non-metallic substrate materials and generally possess better heat conduction properties anyway. An electrode 102 may be disposed above and connected to the LED stack 104.

On a side of the LED stack 104 opposite the electrode 102 (e.g. below), a reflective layer 106 (or mirror as labeled in the diagram) may be formed to reflect light generated by said side of the LED stack 104. With this reflection, this light is not wasted and contributes to the overall light emission, thereby increasing luminous efficiency. The reflective layer 106 may be composed of any suitable materials, such as AgNi, Ni/Ag/Ni/Au, Ag/Ni/Au, AuZn, AuBe, ITO/Ag, ITO/Ag2O/Ag, ITO/Al or Ag/Ti/Ni/Au. An alloy of Ag, Au, Cr, Pt, Pd, Rh, or Al may also be used. During fabrication the reflective layer 106 may have been deposited on the aforementioned side of the LED stack 104 before the substrate 108 was added to the structure.

Beneath the substrate 108, a eutectic layer 110 may have been formed. The use of a eutectic layer 110 allows for eutectic bonds having high bonding strength and good stability at a low process temperature to form between the substrate 108 and the eutectic layer 110 during fabrication of the VLED. Also, eutectics (e.g. AuSn, CuMo, and CuW) have a higher thermal conductivity and a lower coefficient of thermal expansion than the Ag epoxy used in prior art VLED structures as can be observed in Table 1.

TABLE 1

| | Thermal Conductivity | CTE (Coefficient of Thermal |
|---|---|---|
| Material | (W/mK) | Expansion, ppm/K) |
| Epoxy | 0.5 | 18˜65 |
| Ag Epoxy | 0.6˜10 | 20˜65 |
| FR-4 PC Board | 2 | 18.0 |
| Sn | 55 | 25.4 |
| AuSn | 57 | 16.8 |
| Co | 69 | 12.4 |
| Pt | 69 | 9.0 |
| Fe | 82 | 11.6 |
| Ni | 90 | 13.1 |
| CuMo | 170 | 8.0 |
| CuW | 170 | 10.0 |
| Al | 237 | 23.8 |
| Au | 315 | 14.6 |
| Cu | 400 | 16.0 |
| Ag | 427 | 19.4 |

A lower thermal conductivity between the eutectic layer 110 and a lead frame (not shown) or other base connective element for the VLED structure 100 leads to a decreased overall thermal resistance between the active layer of the LED stack 104 and the ambient environment. With the decreased thermal resistance, embodiments of the present invention may have increased light output and reliability at a given operating current when compared to conventional VLEDs, thereby yielding devices with greater luminous efficiency.

Furthermore, the eutectic trait of lower coefficients of thermal expansion and the eutectic bonds themselves may lead to increased reliability when compared to conventional devices. When high temperatures do occur within the device, the eutectic layer 110 should expand and change shape less than the corresponding layers typically comprising Ag epoxy of conventional VLEDs. Also, the eutectic bonds may lead to better adhesion to the substrate 108. For these reasons, the eutectic layer 110 may maintain a closer, constant connection with the substrate 108 over an extended lifetime of the VLED.

As for the eutectic layer 110 itself, it may comprise a single layer or multiple layers of any suitable materials, such as Sn, In, Pb, AuSn, CuSn, AgIn, CuIn, SnPb, SnInCu, SnAgIn, SnAg, SnZn, SnAgCu, SnZnBi, SnZnBiIn, or SnAgInCu. During fabrication of the VLED structure 100, the eutectic layer 110 may be formed by deposition, sputtering, evaporation, electroplating, electroless plating, coating, ink jet, or printing. For some embodiments, the eutectic layer 110 typically has a thickness of 0.5 to 2 μm, although it may range from 0.01 to 100 μm. This typical thickness range may be much thinner than the typical 5 to 20 μm thickness of the Ag epoxy layer in conventional VLEDs. The reduced thickness of the eutectic layer 110 may also improve thermal conductivity of the VLED structure 100 for some embodiments.

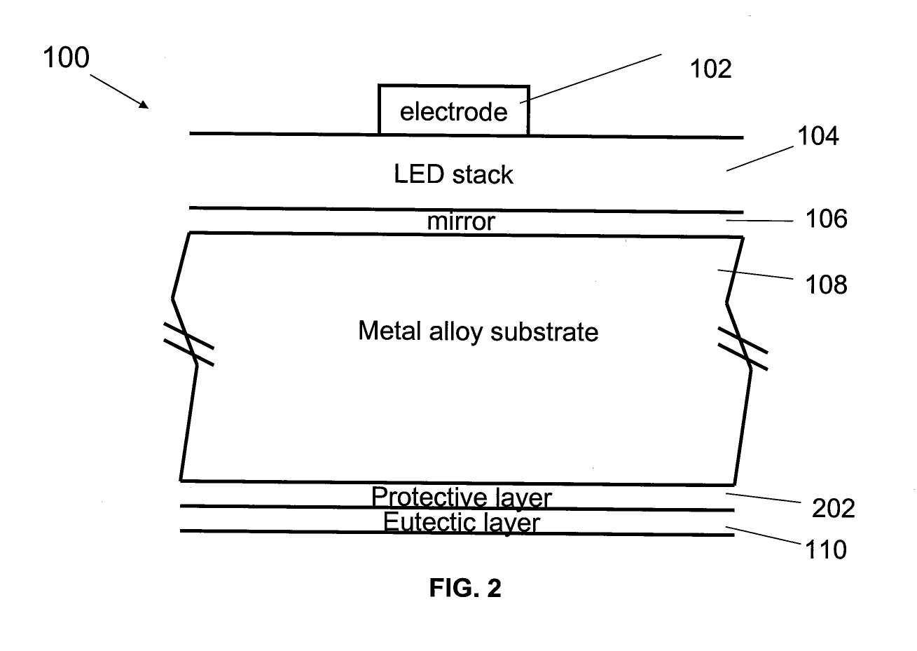

To further increase reliability, some embodiments may also include a metal protective layer 202 interposed between the eutectic layer 110 and the substrate 108, as depicted in the VLED schematic representation of FIG. 2. The metal protective layer 202 may help prevent oxidation and diffusion of constituents within the eutectic layer 110 into the substrate 108, thereby increasing the lifetime of the eutectic layer 110 and hence, the lifetime and reliability of the VLED structure 100 as defined. Typically having a thickness of 0.01 to 100 μm, the metal protective layer 202 may comprise Ni, W, Mo, Pt, Ta, Rh, Au, V, TiW, TaN, or Ni—Co and may be formed via deposition, sputtering, evaporation, electroplating, electroless plating, coating, ink jet, and printing.

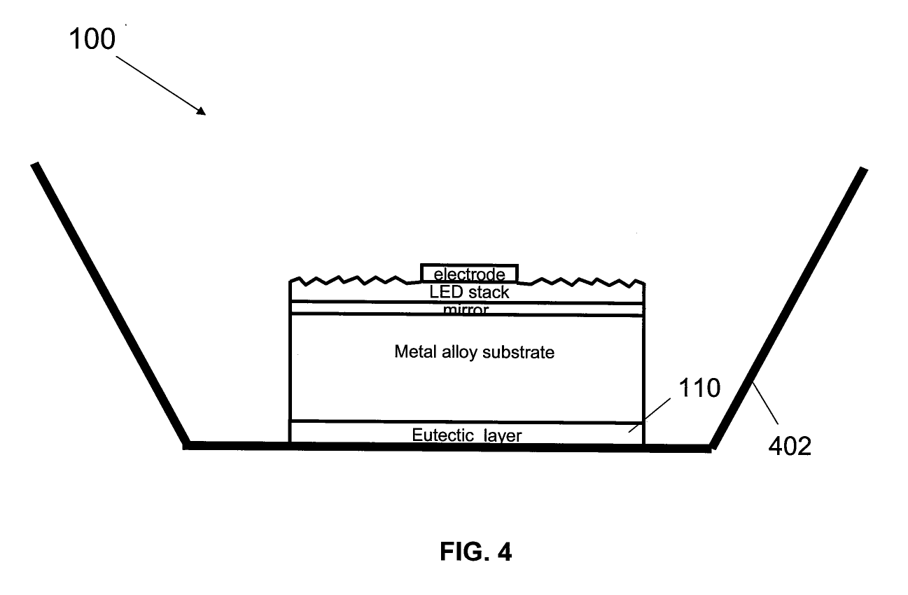

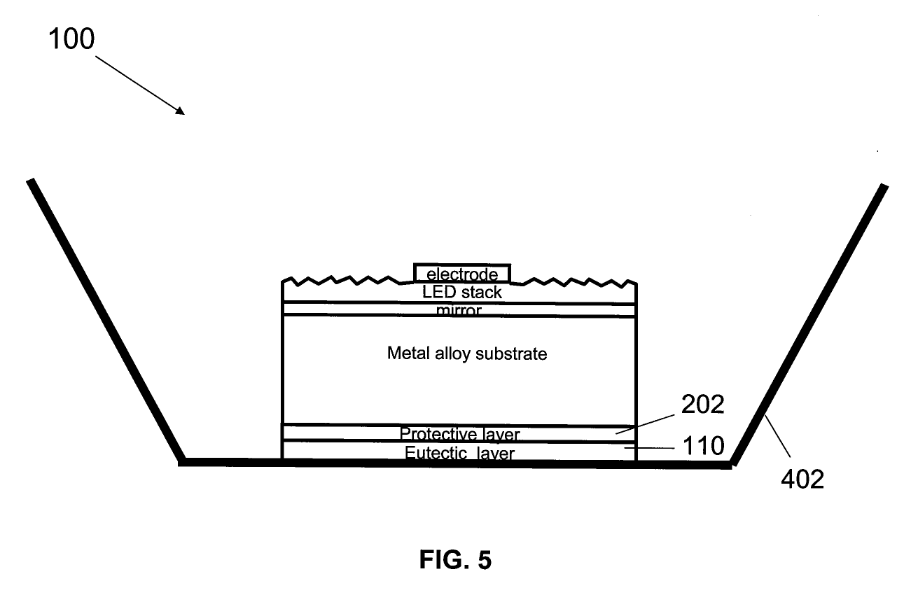

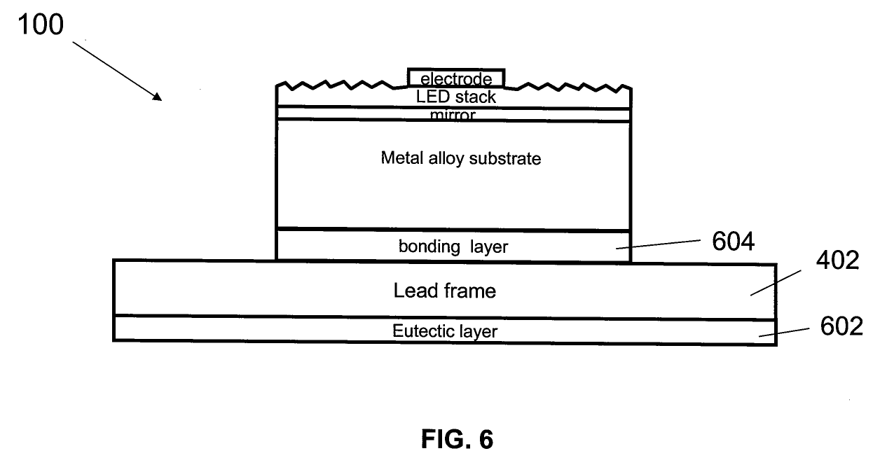

In order to have a means of mounting the VLED structure 100 to a PCB pad or other suitable surface, embodiments of the present invention may include a lead frame 402 as illustrated in FIG. 4. The lead frame 402 may be disposed beneath and connected to the eutectic layer 110 via eutectic bonding in an effort to benefit from the increased heat conduction and reliability that accompanies eutectics. As described above and illustrated further in FIG. 5, some embodiments with a lead frame 402 and a eutectic layer 110 may also have a metal protective layer 202 interposed between the metal-based substrate 108 and the eutectic layer 110. For some embodiments, a second eutectic layer 602, as depicted in FIG. 6, may have been formed beneath the lead frame 402 in an effort to provide a strong, reliable connection with low thermal resistance to the mounting surface. The second eutectic layer 602 may be composed of the same materials, be formed in the same manner, and possess the same thickness as the eutectic layer 110 described above. For embodiments with a second eutectic layer 602, the eutectic layer 110 may be replaced with a bonding layer 604 that may comprise any suitable material, such as Ag epoxy, for bonding the substrate 108 to the lead frame.

Furthermore, embodiments with a second eutectic layer 602 may have a second metal protective layer (not shown) interposed between the second eutectic layer 602 and the lead frame 402. The second metal protective layer may help prevent oxidation and diffusion of constituents within the second eutectic layer 602 into the lead frame 402, thereby increasing the lifetime of the second eutectic layer 602 and hence, the lifetime and reliability of the VLED structure 100 as defined. Typically having a thickness of 0.01 to 100 μm, the second metal protective layer may comprise Ni, W, Mo, Pt, Ta, Rh, Au, V, TiW, TaN, or Ni—Co and may be formed via deposition, sputtering, evaporation, electroplating, electroless plating, coating, ink jet, and printing.

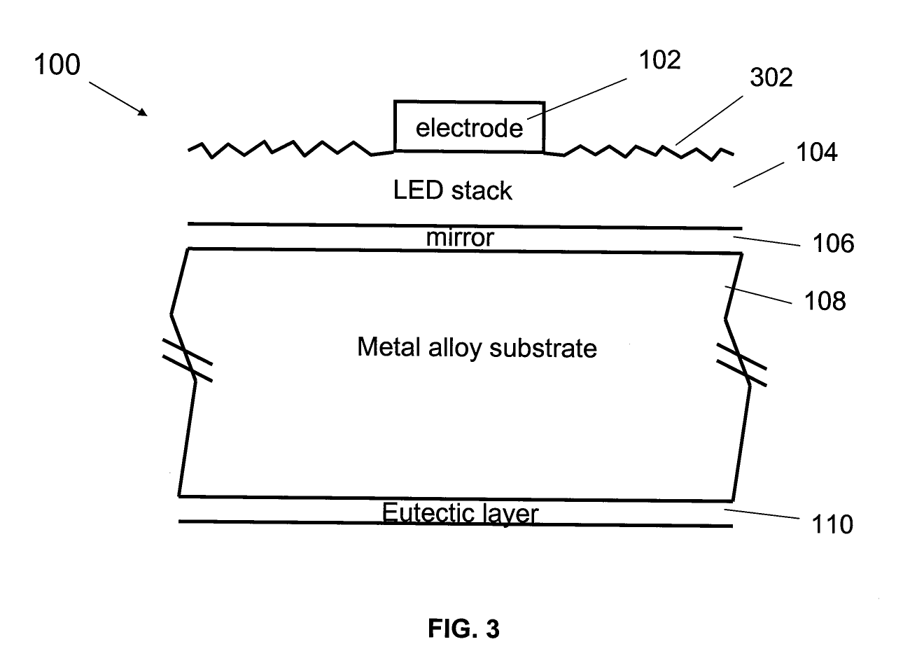

Some embodiments of the present invention may include additional features for certain applications. For some embodiments, for instance, a portion of the surface 302 of the LED stack 104 may be patterned in any manner desired in an effort to improve light extraction as shown in the VLED schematic representation of FIG. 3. Such surface patterning may enhance the brightness of the VLED, thereby increasing its luminous efficiency. Also in some embodiments, the VLED structure 100 shown in any of the figures may be incorporated into an LED device, for example, by encapsulating the structure in a housing with leads provided for external electrical connection to the LED stack 104 and substrate 108.

While the foregoing is directed to embodiments of the present invention, other and further embodiments of the invention may be devised without departing from the basic scope thereof, and the scope thereof is determined by the claims that follow.

1. A light-emitting diode structure comprising:
a substrate comprising at least one of metal and metal alloy materials;
a eutectic layer thermally coupled with the substrate;
a light-emitting diode stack disposed above the substrate; and
an electrode connected to the light-emitting diode stack.

2. The light-emitting diode structure of claim 1, wherein the eutectic layer comprises multiple layers.

3. The light-emitting diode structure of claim 1, wherein the eutectic layer comprises at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

4. The light-emitting diode structure of claim 1, wherein the eutectic layer has a thickness of 0.01 to 100 μm.

5. The light-emitting diode structure of claim 1, wherein the eutectic layer is formed by at least one of deposition, sputtering, evaporation, electroplating, electroless plating, coating, ink jet, and printing.

6. The light-emitting diode structure of claim 1, wherein the substrate comprises a single layer or multiple layers.

7. The light-emitting diode structure of claim 1, wherein the substrate comprises at least one of Cu, Ni, Ag, Au, Al, Cu—Co, Ni—Co, Cu—W, Cu—Mo, Ni/Cu, and Ni/Cu—Mo.

8. The light-emitting diode structure of claim 1, wherein the substrate has a thickness of 10 to 400 μm.

9. The light-emitting diode structure of claim 1, further comprising a reflective layer disposed between the substrate and the light-emitting diode stack.

10. The light-emitting diode structure of claim 9, wherein the reflective layer comprises at least one of AgNi, Ni/Ag/Ni/Au, Ag/Ni/Au, Ag/Ti/Ni/Au, AuZn, AuBe, ITO/Ag, ITO/Ag2O/Ag, ITO/Al, and an alloy containing Ag, Au, Cr, Pt, Pd, Rh, and Al.

11. The light-emitting diode structure of claim 1, wherein the light-emitting diode stack is at least one of AlGaInN and AlGaInP.

12. The light-emitting diode structure of claim 1, wherein a portion of a surface of the light-emitting diode stack is patterned to improve light extraction.

13. The light-emitting diode structure of claim 1, further comprising a lead frame for external connection disposed beneath the eutectic layer.

14. A light-emitting diode structure comprising:
a substrate comprising at least one of metal and metal alloy materials;
a eutectic layer thermally coupled with the substrate;
a metal protective layer disposed between the substrate and the eutectic layer;
a light-emitting diode stack disposed above the substrate; and
an electrode connected to the light-emitting diode stack.

15. The light-emitting diode structure of claim 14, wherein the metal protective layer comprises at least one of Ni, W, Mo, Pt, Ta, Rh, Au, V, TiW, TaN, and Ni—Co.

16. The light-emitting diode structure of claim 14, wherein the metal protective layer has a thickness of 0.01 to 100 μm.

17. The light-emitting diode structure of claim 14, wherein the metal protective layer is formed by at least one of deposition, sputtering, evaporation, electroplating, electroless plating, coating, ink jet, and printing.

18. A light-emitting diode comprising:
a housing;
a substrate comprising at least one of metal and metal alloy materials;
a eutectic layer thermally coupled with the substrate;
a light-emitting diode stack disposed above the substrate; and
electrodes providing external electrical connection to the light-emitting diode stack and substrate.

19. The light-emitting diode of claim 18, further comprising a metal protective layer disposed between the substrate and the eutectic layer.

20. The light-emitting diode of claim 18, further comprising a reflective layer disposed between the substrate and the light-emitting diode stack.

21. The light-emitting diode of claim 18, wherein a portion of a surface of the light-emitting diode stack is patterned to improve light extraction.

22. A light-emitting diode structure comprising:
a eutectic layer;
a lead frame for external connection disposed adjacent to the eutectic layer;
a bonding layer disposed between the lead frame and a substrate, wherein the substrate comprises at least one of metal and metal alloy materials;
a light-emitting diode stack disposed above the substrate; and
an electrode connected to the light-emitting diode stack.

23. The light-emitting diode structure of claim 22, wherein the eutectic layer comprises multiple layers.

24. The light-emitting diode structure of claim 22, wherein the eutectic layer comprises at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

25. The light-emitting diode structure of claim 22, wherein the eutectic layer has a thickness of 0.01 to 100 μm.

26. The light-emitting diode structure of claim 22, wherein the eutectic layer is formed by at least one of deposition, sputtering, evaporation, electroplating, electroless plating, coating, ink jet, and printing.

27. The light-emitting diode structure of claim 22, wherein the substrate comprises a single layer or multiple layers.

28. The light-emitting diode structure of claim 22, wherein the substrate comprises at least one of Cu, Ni, Ag, Au, Al, Cu—Co, Ni—Co, Cu—W, Cu—Mo, Ni/Cu, and Ni/Cu—Mo.

29. The light-emitting diode structure of claim 22, wherein the substrate has a thickness of 10 to 400 μm.

30. The light-emitting diode structure of claim 22, further comprising a reflective layer disposed between the substrate and the light-emitting diode stack.

31. The light-emitting diode structure of claim 30, wherein the reflective layer comprises at least one of AgNi, Ni/Ag/Ni/Au, Ag/Ni/Au, Ag/Ti/Ni/Au, AuZn, AuBe, ITO/Ag, ITO/Ag2O/Ag, ITO/Al, and an alloy containing Ag, Au, Cr, Pt, Pd, Rh, and Al.

32. The light-emitting diode structure of claim 22, wherein the light-emitting diode stack is at least one of AlGaInN and AlGaInP.

33. The light-emitting diode structure of claim 22, wherein a portion of a surface of the light-emitting diode stack is patterned to improve light extraction.

34. The light-emitting diode structure of claim 22, wherein the bonding layer is a second eutectic layer comprising at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

35. A light-emitting diode structure comprising:
a eutectic layer;
a lead frame for external connection disposed above the eutectic layer;
a metal protective layer disposed between the lead frame and the eutectic layer;
a bonding layer disposed between the lead frame and a substrate, wherein the substrate comprises at least one of metal and metal alloy materials;
a light-emitting diode stack disposed above the substrate; and
an electrode connected to the light-emitting diode stack.

36. The light-emitting diode structure of claim 35, wherein the metal protective layer comprises at least one of Ni, W, Mo, Pt, Ta, Rh, Au, V, TiW, TaN, and Ni—Co.

37. The light-emitting diode structure of claim 35, wherein the metal protective layer has a thickness of 0.01 to 100 μm.

38. The light-emitting diode structure of claim 35, wherein the metal protective layer is formed by at least one of deposition, sputtering, evaporation, electroplating, electroless plating, coating, ink jet, and printing.

39. The light-emitting diode structure of claim 35, wherein the bonding layer is a second eutectic layer comprising at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

40. A light-emitting diode structure comprising:
a first eutectic layer thermally coupled to a lead frame for external connection;
a first metal protective layer disposed between the lead frame and the first eutectic layer;
a second eutectic layer disposed above the lead frame and thermally coupled to a substrate, wherein the substrate comprises at least one of metal and metal alloy materials;
a second metal protective layer disposed between the second eutectic layer and the substrate;
a light-emitting diode stack disposed above the substrate; and
an electrode connected to the light-emitting diode stack.

41. The light-emitting diode structure of claim 40, wherein the first and second eutectic layers comprise at least one of Sn, In, Pb, AuSn, CuSn, AgIn, CuIn, SnPb, SnInCu, SnAgIn, SnAg, SnZn, SnAgCu, SnZnBi, SnZnBiIn, and SnAgInCu.

42. The light-emitting diode structure of claim 40, wherein the first and second metal protective layers comprise at least one of Ni, W, Mo, Pt, Ta, Rh, Au, V, TiW, TaN, and Ni—Co.

43. The light-emitting diode structure of claim 40, further comprising a reflective layer disposed between the substrate and the light-emitting diode stack.

44. The light-emitting diode structure of claim 40, wherein a portion of a surface of the light-emitting diode stack is patterned to improve light extraction.
